(19) United States
(12) Patent Application Publication
(10) Pub. No.: US 2024/0150893 A1
(43) Pub. Date: May 9, 2024

(54) APPARATUS AND METHOD FOR COATING A SUBSTRATE

(71) Applicant: FRAUNHOFER-GESELLSCHAFT ZUR FÖRDERUNG DER ANGEWANDTEN FORSCHUNG E.V., MUNICH (DE)

(72) Inventor: RALF BANDORF, BRAUNSCHWEIG (DE)

(73) Assignee: FRAUNHOFER-GESELLSCHAFT ZUR FÖRDERUNG DER ANGEWANDTEN FORSCHUNG E.V., MUNICH (DE)

(21) Appl. No.: 18/411,274

(22) Filed: Jan. 12, 2024

Related U.S. Application Data
(63) Continuation-in-part of application No. PCT/EP2022/069530, filed on Jul. 13, 2022.

(30) Foreign Application Priority Data
Jul. 13, 2021 (DE) 102021207398.0

(51) Int. Cl. C23C 16/44; C23C 16/02; C23C 16/56

(52) U.S. Cl. CPC C23C 16/4404; C23C 16/0227; C23C 16/56

(57) ABSTRACT

An apparatus (1) for coaling a substrate (2) has a vacuum chamber (10) and at least one vacuum pump (11) which is designed to evacuate the vacuum chamber (10). At least one substrate mount (20) is arranged inside the vacuum chamber (10) and is designed to receive the substrate (2) to be coated. At least one coating-producing device is arranged inside the vacuum chamber (10). The vacuum chamber (10) also contains at least one cleaning device (4), which includes at least one adhesion roller (40). The adhesive roller (40) is configured to be passed over a surface (201) of the substrate (2) and is designed to bind particles (25) adhering to the substrate (2). A method for coating a substrate (2) utilizes the aforementioned apparatus.

### RELATED APPLICATIONS

This is a Continuation-in-part of International Application No. PCT/EP2022/069530 filed Jul. 13, 2022, and published as WO 2023/285500A1. Priority is claimed to DE 10 2021 207 398.0 filed Jul. 13, 2021. The contents of the aforementioned applications are incorporated by reference in their entirety.

### SUMMARY

The invention relates to an apparatus for coating a substrate having a vacuum chamber and at least one vacuum pump, which is designed to evacuate the vacuum chamber, and having at least one substrate mount, which is arranged inside the vacuum chamber and is designed to receive the substrate to be coated, at least one device for producing a coating being also arranged in the vacuum chamber. The invention also relates to a corresponding coating method.

PVD, CVD and PECVD coating processes are known in practice, with which thin layers can be produced on surfaces. For example, electrically insulating layers can be produced on electrically conductive components. Other applications are e.g. coatings on architectural glass or wear protection layers or sliding layers on machine components.

If there are particles on the surface to be coated, these particles can lead to defects or shading during the production of the coating. This can have a negative impact on the quality of the coating.

In order to solve this problem, it is known to clean the surfaces to be coated before introducing them into the vacuum chamber, for example by blowing them off with compressed air, by cleaning them in an ultrasonic bath or by brushing them. However, these known processes have the disadvantage that the components to be coated have to be transported to the coating apparatus after cleaning and in so doing can be contaminated with particles again. It is also known to bring the substrates to be coated to an elevated temperature in a vacuum in order to thus remove organic particles by oxidation, reduction or thermal decomposition. However, inorganic contaminations are difficult or impossible to remove in this way. In addition, such a cleaning step in a vacuum is time-consuming and energy-intensive.

On the basis of the prior art, the object of the invention is therefore to increase the layer quality of a coating applied in a vacuum coating process.

According to the invention, this object is achieved by an apparatus according to claim 1 and a method according to claim 7. Advantageous further developments of the invention can be found in the subclaims.

According to one aspect of the invention, an apparatus for coating a substrate is proposed. The apparatus according to the invention contains at least one vacuum chamber with at least one vacuum pump, which is designed to evacuate the vacuum chamber. Further elements known per se can be arranged on or in the vacuum chamber, such as partial pressure gauges, total pressure gauges or devices for diagnosing or monitoring the layer quality, the layer thickness or the surface of the substrate to be coated. The at least one vacuum pump can be any vacuum pump suitable for the planned final pressure, for example a cryogenic pump, a turbo molecular pump, a diffusion pump, a scroll pump, a rotary vane pump or any other vacuum pump.

Inside the vacuum chamber there is at least one substrate mount, which is designed to receive the substrate to be coated. The substrate mount can be designed and intended to move the substrate inside the vacuum chamber, for example from the effective range of a diagnostic device to a device for producing a coating or, after coating has taken place, back to a diagnostic device or to an airlock which allows the substrate to be removed from the vacuum chamber without breaking the vacuum.

In some embodiments of the invention, the substrate mount can contain a heating and/or cooling device to bring the substrate to a predeterminable temperature. In other embodiments of the invention, the substrate mount can contain at least one measuring device which can, for example, record the temperature, electrical resistance, optical properties, layer thickness, defect density or other measured values of the substrate or the applied coating in situ.

The vacuum chamber also contains at least one device for producing a coating. The device for producing a coating can be designed to apply a coating to at least one surface of the substrate or at least a partial area of the surface of the substrate by means of a PVD or a CVD or PECVD process. For example, the device for producing a coating can be selected from at least one plasma coating source and/or at least one magnetron and/or at least one evaporation source. The coating produced in this way can be electrically conductive or insulating. It can be optically transparent or opaque. As an optical filter, it can transmit part of the electromagnetic spectrum or reflect another part.

According to the invention, it is now proposed that the vacuum chamber additionally contains at least one cleaning apparatus which contains at least one adhesion roller which can be guided over a surface of the substrate and which is designed to bind particles adhering to the substrate. In this way, an uncleaned or pre-cleaned substrate can be introduced into the vacuum chamber and cleaned immediately before the coating is applied. Recontamination with particles is ruled out, on the one hand, since the coating can be applied immediately after cleaning so that recontamination is ruled out in terms of time alone. In addition, the interior of the evacuated vacuum chamber can have a lower particle density so that the vicinity of the substrate or the surface to be coated do not have any sources of dirt, the particles of which can get onto the surface to be coated. If the cleaning apparatus and the device for producing a coating are arranged in one and the same vacuum chamber, it is possible to reduce the particle loading density of the surface to be coated compared to known apparatus.

In some embodiments of the invention, the cleaning apparatus can be arranged inside the vacuum chamber in which the coating on the surface of the substrate is also produced. The device for producing a coating, for example at least one plasma coating source and/or at least one magnetron and/or at least one evaporation source, is thus located in the same vacuum chamber as the cleaning apparatus.

The cleaning methods known from the prior art, for example blowing off with compressed air or ultrasonic cleaning in liquids, cannot be used in a vacuum. According to one embodiment of the invention, it is therefore proposed to roll an adhesion roller over the surface of the substrate so that adhering particles are detached from the substrate and adhere to the adhesion roller. For this purpose, the adhesion roller can be provided with a drive which, on the one hand, renders possible a linear or circular movement of the adhesion roller on the substrate and, on the other hand, generates a contact pressure so that adhering particles are transferred to the adhesion roller with sufficient probability and, on the other hand, damage to the substrate surface is avoided. The drive unit of the adhesion roller can be arranged inside or outside the vacuum chamber. The movement can be transmitted via push rods from a drive arranged outside the vacuum chamber to the adhesion roller arranged inside the vacuum chamber. The push rods can be sealingly received in the wall of the vacuum chamber via sliding seals or bellows.

In some embodiments of the invention, the adhesion roller can contain or consist of an elastomer. An elastomer can bind particles mechanically or electrostatically and thus ensure a good cleaning result or freedom from particles on the surface to be coated.

In some embodiments of the invention, the apparatus can further contain an electrical voltage source with which a charge can be applied to the adhesion roller. This can support the electrostatic bonding of the particles to the adhesion roller. The charge can be applied without contact by exposing the adhesion roller to an electric field. In other embodiments of the invention, the adhesion roller or the surface thereof can be exposed to a plasma. In yet other embodiments of the invention, the adhesion roller can be in mechanical contact with a conductive electrode which applies an electrical charge to the adhesion roller.

In some embodiments of the invention, the apparatus can further contain at least one collecting apparatus which can be guided over the surface of the adhesion roller and which is designed to bind particles adhering to the adhesion roller. This makes it possible to clean the surface of the adhesion roller in a vacuum so that the operating time between necessary maintenance intervals can be extended.

In some embodiments of the invention, the collection apparatus can contain or consist of an adhesive film over which the adhesion roller is rolled off, particles adhering to the adhesion roller being transferred to the adhesive film. The adhesive film can be unrolled via a supply roller and rolled up on a collecting roller after use in order to save installation space and extend the operating time between maintenance intervals.

The coating, although used in the singular in the present description, can be composed of a plurality of thin layers applied on top of one another, for example to realize interference filters or to improve the adhesive strength. In some embodiments of the invention, the coating can therefore be applied in a plurality of sequential process steps. In some embodiments of the invention, cleaning with the cleaning apparatus according to the invention can be carried out between at least two of the sequential process steps in order to remove particles adhering to the substrate or to reduce the number thereof.

In some embodiments of the invention, the apparatus can comprise a plurality of adhesion rollers. Thus, if an adhesion roller is dirty, another adhesion roller can be used without having to open the vacuum chamber. This allows the operating time of the apparatus to be extended between necessary maintenance intervals.

In some embodiments of the invention, the apparatus can be designed to remove a first adhesion roller from the vacuum chamber via an airlock and to introduce a second adhesion roller into the vacuum chamber via the airlock. This means that if an adhesion roller becomes dirty, another adhesion roller can be used without having to open the vacuum chamber. This allows the operating time of the apparatus to be extended between necessary maintenance intervals.

In some embodiments of the invention, the vacuum chamber can be evacuated to less than about 1·10⁻⁵ mbar with the at least one vacuum pump. In other embodiments of the invention, the vacuum chamber can be evacuated to less than about 1·10⁻⁶ mbar with the at least one vacuum pump. In yet other embodiments of the invention, the vacuum chamber can be evacuated to less than 1·10⁻⁷ bar with the at least one vacuum pump. This avoids contamination from the residual gas, which can have a negative effect on the quality of the coating.

In some embodiments of the invention, the coating applied according to the invention can have a layer thickness of about 1 nm to about 20 μm or about 2 nm to about 8 μm. In other embodiments of the invention, the layer thickness can be between about 10 nm and about 80 nm. In yet other embodiments of the invention, the layer thickness can be between about 5 nm and about 100 nm. In particular thin coatings require the surface to be coated to be free from particles since even small particles lead to imperfections or pinholes in the coating.

In some embodiments of the invention, particles which have a diameter from about 50 nm to about 10 μm or from about 90 nm to about 1 μm or from about 100 nm to about 500 nm can be removed from the surface of the substrate. According to the prior art, such small particles are difficult to remove from the surface, yet have a lasting adverse effect on the quality of the applied coating, in particular in the case of thin layer thicknesses. The cleaning apparatus proposed according to the invention which uses an adhesion roller also renders possible the removal of very small particles down to a few nanometers so that high-quality coatings can be produced.

In some embodiments of the invention, the substrate can be or contain a rigid material. For the purposes of the present invention, a rigid material is one that cannot be wound like a film web. Minor deformability is not important here, as this can also be present in a rigid material within the meaning of the invention.

### BRIEF DESCRIPTION OF THE DRAWINGS

The invention shall be explained in more detail below on the basis of drawings without restricting the general concept of the invention. In the drawings,

FIG. 1 shows a cross-section through a coated substrate.

FIG. 2 shows a first embodiment of an apparatus according to the invention.

FIG. 3 shows a second embodiment of an apparatus according to the invention.

### DETAILED DESCRIPTION

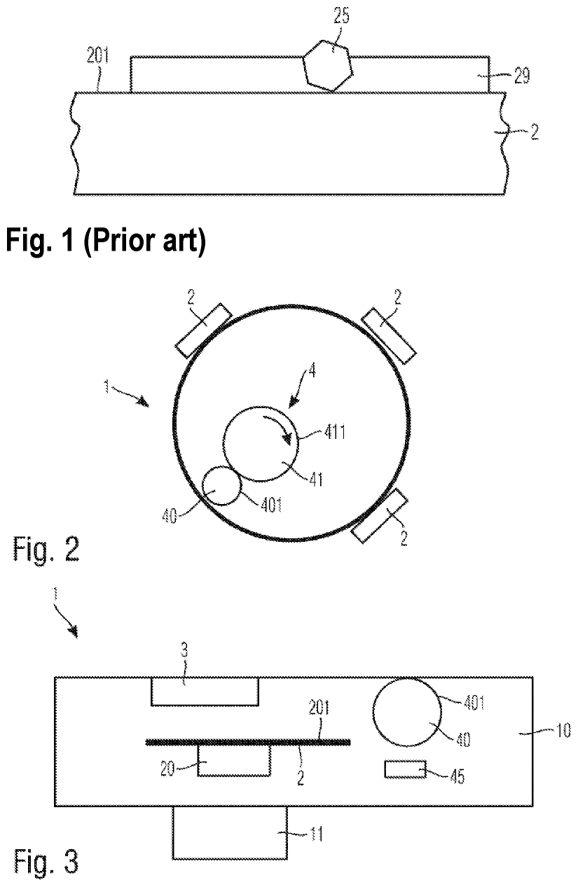

FIG. 1 shows a coated substrate 2 according to the prior art. The substrate 2 has a surface 201 to be coated. The substrate 2 can, for example, be a semiconductor component which shall be provided with semiconducting and/or conducting and/or insulating layers. In other embodiments of the invention, the substrate 2 can be a tool or a machine element. In yet other embodiments of the invention, the substrate 2 can be an architectural glass or a vehicle glazing.

A coating 29 is located on the surface 201. The coating can be, for example, an insulating layer, a conductor track, a sliding layer, a corrosion protection layer or an optical coating layer or filter layer, for example an infrared-reflecting coating. In some embodiments of the invention, the coating 29 can have a thickness from about 5 nm to about 500 nm or from about 100 nm to about 500 nm or from about 10 nm to about 100 nm.

Furthermore, FIG. 1 shows a particle 25 by way of example. The particles 25 represent a contamination, for example of organic or inorganic fine dusts, which are transported with the atmospheric air onto the substrate 2 where they adhere. The particles 25 can, for example, have a diameter from about 50 nm to about 10 μm or from about 90 nm to 1 μm or from about 100 nm to about 500 nm. FIG. 1 shows that the diameter of the particles 25 is equal to or slightly larger than the thickness of the coating 29. In some embodiments, the diameter of the particles 25 is between 80% and 120% of the thickness of the coating 29. Therefore, the particles 25 lead to a defect or damaged area in the coating 29. This can result in the substrate 2 becoming unusable and having to be discarded during the quality control of the manufactured products.

According to the prior art, adhering particles 25 are removed from the substrate 2 outside the vacuum chamber of the coating system, for example by compressed air or ultrasonic cleaning. The substrate 2 is then introduced into the vacuum chamber of the coating system where it is provided with the coating 29. The disadvantage of this procedure is that between the end of the cleaning step and the introduction into the vacuum chamber of the coating system, contaminations in the form of particles 25 can again reach the surface 201 of the substrate 2.

FIG. 2 shows a cross-section of a first embodiment of an apparatus according to the present invention. FIG. 2 shows the interior of a box coater having a vacuum chamber (not shown) which can be evacuated by means of a vacuum pump (also not shown). A plurality of substrates 2 can then be coated by means of a device (not shown) for producing a coating in a PVD or a CVD process or a PECVD process.

FIG. 2 shows a cleaning apparatus 4 according to the present invention. This apparatus comprises an adhesion roller 40, which contains or consists of an elastomer. The surface 401 of the adhesion roller 40 is rolled over the surfaces 201 of the substrates 2 so that particles 25 adhering to the substrates 2 adhere to the adhesion roller 40 and are thus removed from the substrate 2.

A collecting apparatus 41 is available for cleaning the surface 401 of the adhesion roller 40. The collecting apparatus 41 has a surface 411 which is rolled over the surface 401 of the adhesion roller 40 and binds particles adhering to the adhesion roller 40. The adhesion roller 40 cleaned in this way can then either be guided over the identical substrate 2 again for the purpose of fine cleaning or be guided over another substrate 2 so that all substrates inside the vacuum chamber are gradually cleaned and are thus prepared for coating.

The collecting apparatus 41 itself may be a roller and can, for example, contain or carry an adhesive tape, which is disposed of after a single use together with the particles adhering to the adhesion roller 40.

Both the adhesion roller and the collecting apparatus can be made of materials which have a comparatively high vapor pressure. This means that the cleaning apparatus 4 according to the invention can also be used in a high vacuum at a base pressure of 1×10⁻⁵ mbar or 1×10⁻⁶ mbar or 1×10⁻⁷ mbar or less.

FIG. 3 shows a second embodiment of the present invention. Equal components of the invention are provided with equal reference signs so that the following description is limited to the essential differences.

FIG. 3 shows a vacuum chamber 10, which is connected to a vacuum pump 11. The vacuum pump 11 can be, for example, a turbomolecular pump, a cryogenic pump or another gas-conveying or gas-binding pump which is known per se. This pump is designed and intended to generate a pressure of 1×10⁻⁵ mbar or 1×10⁻⁶ mbar or 1×10⁻⁷ mbar or less inside the vacuum chamber 10.

Inside the vacuum chamber 10, there is a substrate mount 20, on which the substrate 2 to be coated is received. The substrate mount 20 is designed and intended to move and position the substrate 2 inside the vacuum chamber 10.

Furthermore, the coating system contains a cleaning apparatus 4 in the form of an adhesion roller 40 having a surface 401. The adhesion roller 40 is designed to be rolled over the surface 201 of the substrate 20 in order to remove adhering particles in this way.

In order to increase the effectiveness, an optional electrical voltage source 45 can be provided, which applies a charge to the surface 401 of the adhesion roller 40, for example by means of an electrical field, a plasma or direct contact. In some embodiments of the invention, the adhesion roller 40 charged electrostatically in this way can bind particles 25 from the surface 201 of the substrate 2 with greater efficiency.

After the substrate 2 or at least part of the surface 201 thereof has been cleaned and freed from particles in this way, it can be moved inside the same vacuum chamber 10 without breaking the vacuum into the effective range of a device 3 in order to produce a coating. The coating 29 is then applied in a PVD or a CVD or a PECVD process by means of the device 3.

Since the surface 201 has also been cleaned of very small particles, for example down to a diameter of 100 nm, before the coating is applied, the coating 29 can be of a higher quality than can be obtained with known methods and apparatus.

Of course, the invention is not limited to the illustrated embodiments. The above description should therefore not to be regarded as limiting, but as explanatory. The following claims shall be understood as meaning that a stated feature is present in at least one embodiment of the invention. This does not exclude the presence of further features. Insofar as the claims and the above description define “first” and “second” embodiments or “first” and “second” features, this designation is used to distinguish between two similar embodiments or features without establishing an order of priority.

What is claimed is:

1. An apparatus (1) for coating a substrate (2) having a substrate surface (201), comprising:
a vacuum chamber (10) and at least one vacuum pump (11) configured to evacuate the vacuum chamber (10);
at least one substrate mount (20) arranged inside the vacuum chamber (10) and configured to receive the substrate (2) to be coated: and
at least one device (3) arranged inside the vacuum chamber and configured to produce a coating (29);
wherein:
the vacuum chamber (10) has at least one cleaning apparatus (4) comprising at least one adhesion roller (40) having a surface (401), the adhesion roller (40) configured to be guided over the substrate surface (201) and bind particles (25) adhering to the substrate (2).

2. The apparatus according to claim 1, wherein the adhesion roller (40) comprises an elastomer.

3. The apparatus according to claim 1, further comprising an electrical voltage source (45) configured to apply a charge to the adhesion roller (40).

4. The apparatus according to claim 1, further comprising at least one collecting apparatus (41) arranged to be guided over the surface (401) of the adhesion roller (40) and configured to bind particles adhering to the surface (401) of the adhesion roller (40).

5. The apparatus according to claim 4, wherein the collecting apparatus (41) has an adhesive surface (411) configured to bind particles adhering to the surface (401) of adhesion roller (40).

6. The apparatus according to claim 1, wherein:
the at least one device (3) for producing a coating (29) is one or more selected from the group consisting of a plasma coating source, a magnetron, and an evaporation source, and/or
the substrate mount (20) is configured to heat or cool the substrate.

7. The apparatus according to claim 1, further comprising:
at least one collecting apparatus (41) arranged to be guided over the surface (401) of the adhesion roller (40) and configured to bind particles adhering to the surface (401) of the adhesion roller (40); wherein:
the adhesion roller (40) comprises an elastomer; and
the collecting apparatus (41) has an adhesive surface (411) configured to bind particles adhering to the surface (401) of adhesion roller (40).

8. The apparatus according to claim 7, further comprising:
an electrical voltage source (45) configured to apply a charge to the adhesion roller (40).

9. The apparatus according to claim 1, wherein:
the at least one device (3) for producing a coating (29) is one or more selected from the group consisting of a plasma coating source, a magnetron, and an evaporation source, and/or
the substrate mount (20) is designed to heat or cool the substrate.

10. A method for coating a substrate, comprising:
providing an apparatus in accordance with claim 1;
guiding the adhesion roller (40) over the substrate surface (201) to bind particles (25) on the substrate (2) to a surface (401) of the adhesion roller (40), thereby removing the particles (25) from the substrate (2); and
producing a coating (29) on the substrate surface (201), after guiding the adhesion roller (40) and removing the particles (25) from the substrate (2).

11. The method according to claim 10, comprising:
prior to guiding the adhesion roller (40) over the substrate surface (201), receiving the substrate (2) onto the substrate mount (20), the substrate (2) remaining on the substrate mount (20) while guiding the adhesion roller (40).

12. The method according to claim 10, further comprising:
prior to guiding the adhesion roller (40) over the substrate surface (201), evacuating the vacuum chamber (10) to less than 1×10⁻⁶ mbar by means of the at least one vacuum pump (11).

13. The method according to claim 10, comprising:
electrically charging the adhesion roller (40), prior to, or while, guiding the adhesion roller (40).

14. The method according to claim 10, further comprising:
cleaning the adhesion roller (40) by guiding a collecting apparatus (41) over the surface (401) of the adhesion roller (40) to thereby bind particles adhering to the adhesion roller (40), to the collecting apparatus (41).

15. The method according to claim 14, comprising:
cleaning the adhesion roller (40) with the collecting apparatus (41), while simultaneously guiding the adhesion roller (40) over the substrate surface (201).

16. The method according to claim 10, comprising:
producing the coating (29) in a plurality of coating steps; and
removing particles (25) adhering to the substrate between at least two of the coating steps by guiding the adhesion roller (40) of the cleaning apparatus (4) over the substrate (2).

17. A method for coating a substrate (2), comprising:
introducing the substrate (2) into a vacuum chamber (10) having at least one vacuum pump (11) configured evacuate the vacuum chamber (10);
removing adhering particles from a surface (201) of the substrate (2) by means of a cleaning apparatus (4), which comprises at least one adhesion roller (40) that is guided over a surface (201) of the substrate (2) and in so doing binds particles (25) adhering to the substrate (2); and
producing a coating (29) on the surface (201) of the substrate (2).

18. The method according to claim 17, comprising:
receiving the substrate (2) onto a substrate mount (20) arranged inside the vacuum chamber (10), the substrate (2) remaining on the substrate mount (20) at least during the removal of adhering particles (25) and the production of the coating (29).

19. The method according to claim 17, comprising:
evacuating the vacuum chamber (10) to less than about 1×10⁻⁶ mbar by means of the at least one vacuum pump (11);
producing the coating (29) on the surface (201) of the substrate (2) to have a layer thickness from 1 nm to 20 μm; and
removing particles (25) having a diameter between 80% and 120% of the layer thickness of the coating (29).

20. The method according to claim 19, comprising:
removing particles having a diameter from 50 nm to 500 nm.

21. The method according to claim 17, comprising:
cleaning the adhesion roller (40) by guiding a collecting apparatus (41) over the surface (401) of the adhesion roller (40) to thereby bind particles adhering to the adhesion roller (40), to the collecting apparatus (41).

22. The method according to claim 17, comprising:
producing the coating (29) in a plurality of coating steps; and
removing particles (25) adhering to the substrate between at least two of the coating steps by guiding the adhesion roller (40) of the cleaning apparatus (4) over the substrate (2).

23. The method according to claim 17, wherein the cleaning apparatus (4) is arranged inside the vacuum chamber (10) in which the coating (29) is produced on the surface (201) of the substrate (2).
